(19) United States
(12) Patent Application Publication
(10) Pub. No.: US 2011/0290184 A1
(43) Pub. Date: Dec. 1, 2011

(54) POLY SILICON DEPOSITION DEVICE

(75) Inventors: Ho-Jeong Yu, Incheon (KR); Seong-Eun Park, Gyeonggi-do (KR); Il-Soo Eom, Gyeonggi-do (KR)

(73) Assignee: Semi-Materials Co. Ltd, Gyeonggi-do (KR)

(21) Appl. No.: 13/143,064

(22) PCT Filed: Nov. 25, 2009
(86) PCT No.: PCT/KR2009/006972

§ 371 Date: Aug. 15, 2011

(30) Foreign Application Priority Data
Dec. 31, 2008 (KR) 10200801378462008

(51) Int. Cl. C23C 16/24; C23C 16/455

(52) U.S. Cl. 118/723 R

(57) ABSTRACT

Provided is a poly silicon deposition device, which includes an electrode part, a silicon core rod part, a silicon core rod heating part, a gas supply pipe, and a gas injection part. The electrode part includes a first electrode and a second electrode which are disposed in a bottom of a reactor including a gas inlet for introducing source gas, a gas outlet for discharging gas, and a heating material inlet for introducing a heating material, and are spaced a predetermined distance from each other. The silicon core rod part receives electric current from the first electrode and transmits the electric current to the second electrode to generate heat. The silicon core rod heating part is spaced a predetermined distance from the silicon core rod part and surrounds the silicon core rod part and includes a heater receiving the heating material introduced through the heating material inlet of the reactor. The gas supply pipe is disposed between the heater and the silicon core rod part to supply the source gas introduced through the gas inlet of the reactor, to the silicon core rod part. The gas injection part includes a plurality of nozzles disposed in a surface of the gas supply pipe to discharge the source gas to the silicon core rod part.

### TECHNICAL FIELD

The present disclosure relates to a device for manufacturing poly silicon used as a key component in semiconductor or photovoltaic industries, and more particularly, to a poly silicon deposition device for depositing poly silicon on a surface of a silicon core rod.

### BACKGROUND ART

Quartz or sand may be reduced by carbon to form metal-grade silicon, thereby manufacturing polycrystalline silicon, also called poly silicon, as a key component in semiconductor or photovoltaic industries. Then, the metal-grade silicon is converted to solar cell-grade silicon or semiconductor-grade silicon through a refining process. Refining processes for metal-grade poly silicon may include a Siemens method, a fluidized bed method, a vapor-to-liquid (VLD) deposition method, and a process of directly defining metal-grade silicon.

Of these, the Siemens method is widely used, in which source gas including chlorosilane or monosilane mixed with hydrogen is thermally decomposed and deposited on a silicon core rod to manufacture polycrystalline silicon. In this case, electric current is applied to the silicon core rod such that the silicon core rod entirely generates Joule heat. Silicon has high electric resistance at room temperature, but the electric resistance thereof is significantly decreased at about 1000° C., and thus, the conductivity thereof is increased. Thus, a member for heating the silicon core rod at the initial stage of a poly silicon manufacturing process is required.

For example, a carbon rod may be installed near a silicon core rod in a reactor, and current may be applied to the carbon rod to heat the carbon rod in an initial stage, and thus, heat from the carbon rod heats the silicon core rod. However, in this case, since silicon may also be deposited on the carbon rod, source gas may be inefficiently used, and contamination due to carbon may occur.

In U.S. Pat. No. 6,749,824, an induction coil is installed outside a silicon core rod to initially heat the silicon core rod. In this case, induction heating of silicon may be difficult, and the induction coil may make deposition uneven.

In Japanese Unexamined Patent Application Publication No. 2001-278611, a silicon core rod is initially heated using infrared radiation. In this case, a window disposed in a portion of a reactor is required for the infrared radiation, and thus, the amount of heat lost through the window may increase at high deposition temperature, the quality of silicon deposited near the window is unstable.

### DISCLOSURE

### Technical Problem

Embodiments provide a poly silicon deposition device that initially heats a silicon core rod with high power efficiency to obtain high impurity poly silicon.

Embodiments also provide a poly silicon deposition device that efficiently uses source gas and has high deposition efficiency.

Embodiments also provide a poly silicon deposition device that facilitates monitoring of the inside of a reactor for poly silicon deposition.

### Technical Solution

In one embodiment, a poly silicon deposition device includes: an electrode part including a first electrode and a second electrode which are disposed in a bottom of a reactor including a gas inlet for introducing source gas, a gas outlet for discharging gas, and a heating material inlet for introducing a heating material, and are spaced a predetermined distance from each other; a silicon core rod part receiving electric current from the first electrode and transmitting the electric current to the second electrode to generate heat; a silicon core rod heating part spaced a predetermined distance from the silicon core rod part and surrounding the silicon core rod part and including a heater receiving the heating material introduced through the heating material inlet of the reactor; a gas supply pipe disposed between the heater and the silicon core rod part to supply the source gas introduced through the gas inlet of the reactor, to the silicon core rod part; and a gas injection part including a plurality of nozzles disposed in a surface of the gas supply pipe to discharge the source gas to the silicon core rod part.

The silicon core rod heating part may include: a first heater spaced a predetermined distance from the first silicon core rod to surround the first silicon core rod, and receiving the heating material through the heating material inlet; and a second heater spaced a predetermined distance from the second silicon core rod to surround the second silicon core rod, and receiving the heating material through the heating material inlet, and the gas supply pipe may include: a first gas supply pipe disposed between the first heater and the first silicon core rod to supply the source gas introduced through the gas inlet, to the silicon core rod part; and a second gas supply pipe disposed between the second heater and the second silicon core rod to supply the source gas introduced through the gas inlet, to the silicon core rod part.

The gas injection part may include a plurality of nozzle groups each including at least two nozzles that are spaced a predetermined distance from each other in a height direction of the gas supply pipe, and the nozzle groups may be spaced a predetermined distance from each other around the surface of the gas supply pipe.

The details of one or more embodiments are set forth in the accompanying drawings and the description below. Other features will be apparent from the description and drawings, and from the claims.

### Advantageous Effects

As described above, the heater surrounds the silicon core rod, and source gas introduced through the gas supply pipe between the heater and the silicon core rod is pre-heated by the heater, and then, is injected to the silicon core rod. Thus, power requiring for initially heating the silicon core rod can be efficiently consumed, silicon gas formed by decomposing the source gas can be efficiently deposited on the silicon core rod.

In addition, since the heater surrounds the silicon core rod to uniformly increase the temperature of the surface of the silicon core rod, silicon gas formed by decomposing source gas is efficiently deposited on the silicon core rod. In addition, since the temperature of the heater is lower than that of the silicon core rod, the heater thermally insulates the silicon core rod to prevent heat loss from the silicon core rod, thereby improving energy efficiency.

In addition, the gas injection part includes the nozzle groups each including at least two nozzles that are spaced a predetermined distance from each other in the height direction of the surface of the gas supply pipe. The nozzle groups are spaced a predetermined distance from each other around the surface of the gas supply pipe. Accordingly, silicon gas formed by decomposing source gas discharged from the gas injection nozzles is efficiently deposited on the silicon core rod.

### DESCRIPTION OF DRAWINGS

FIG. 1 is a cross-sectional view illustrating a poly silicon deposition device according to an embodiment.

FIG. 2 is a cross-sectional view taken along line A-A of FIG. 1, which illustrates a first heater of the poly silicon deposition device.

### MODE FOR INVENTION

Reference will now be made in detail to the embodiments of the present disclosure, examples of which are illustrated in the accompanying drawings.

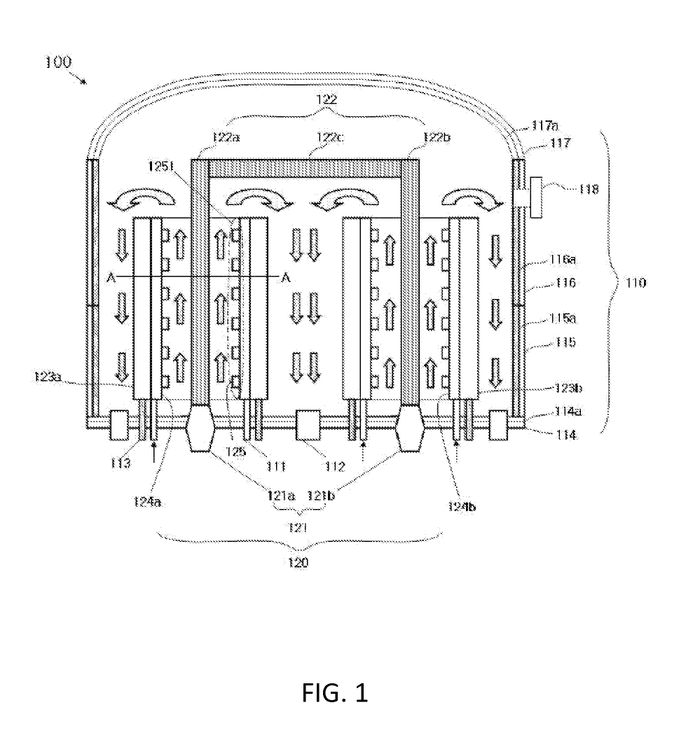

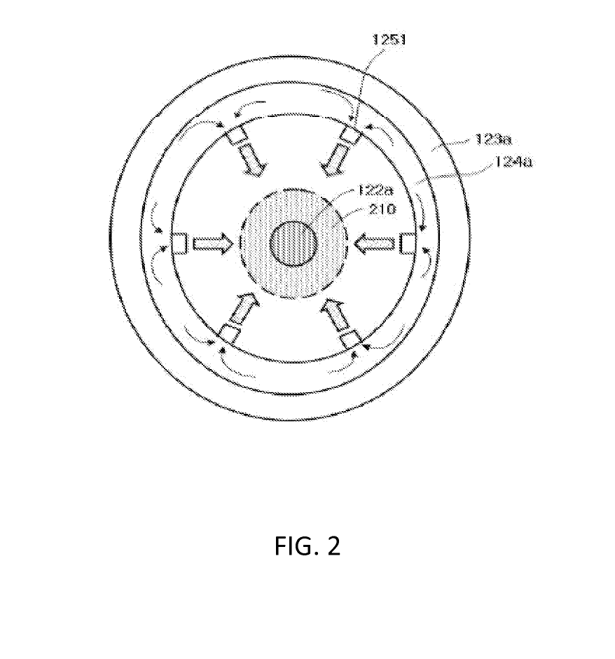

FIG. 1 is a cross-sectional view illustrating a poly silicon deposition device according to an embodiment. FIG. 2 is a cross-sectional view taken along line A-A of FIG. 1, which illustrates a first heater 123a of the poly silicon deposition device.

Referring to FIGS. 1 and 2, a poly silicon deposition device 100 includes: a reactor 110 including a gas inlet 111 for introducing source gas, a gas outlet 112 for discharging gas, and a heating material inlet 113; and a poly silicon deposition part 120 disposed in the reactor 110 and thermally decomposing source gas supplied through the gas inlet 111, to deposit poly silicon. The source gas may be chlorosilane or monosilane, and may be mixed with carrier gas such as hydrogen.

The poly silicon deposition part 120 includes an electrode part 121, a silicon core rod part 122, silicon core rod heating parts 123a and 123b, gas supply pipes 124a and 124b, and a gas injection part including gas injection nozzles 125.

The electrode part 121 supplies current to the silicon core rod part 122, is installed in a bottom of the reactor 110, and includes a first electrode 121a and a second electrode 121b, which are spaced a predetermined distance from each other. The first and second electrodes 121a and 121b may be formed of graphite. The first and second electrodes 121a and 121b are electrically insulated from the bottom of the reactor 110.

The silicon core rod part 122 receives current from the first electrode 121a of the electrode part 121, and transmits the current to the second electrode 121b of the electrode part 121 to generate heat and deposit silicon gas formed by decomposing the source gas. The silicon core rod part 122 includes: a first silicon core rod 122a connected to the first electrode 121a of the electrode part 121 and perpendicular to the bottom of the reactor 110; a second silicon core rod 122b connected to the second electrode 121b of the electrode part 121 and perpendicular to the bottom of the reactor 110; and a third silicon core rod 122c connecting the first and second silicon core rods 122a and 122b to each other.

The silicon core rod heating parts 123a and 123b heat the silicon core rod part 122 before applying current to the silicon core rod part 122. The silicon core rod heating parts 123a and 123b include the first heater 123a and a second heater (also denoted by 123b). The first heater 123a is spaced a predetermined distance from the first silicon core rod 122a to surround the first silicon core rod 122a. A heating material is put in the first heater 123a through the heating material inlet 113 of the reactor 110. The second heater 123b is spaced a predetermined distance from the second silicon core rod 122b to surround the second silicon core rod 122b. A heating material is put in the second heater 123b through the heating material inlet 113 of the reactor 110.

The heating materials put in the first and second heaters 123a and 123b through the heating material inlet 113 of the reactor 110 may include oil having a maximum heating temperature of about 300° C., but are not limited thereto.

The gas supply pipes 124a and 124b are disposed between the silicon core rod part 122 and the first and second heaters 123a and 123b, and supply the source gas introduced through the gas inlet 111 of the reactor 110, to the silicon core rod part 122. The gas supply pipes 124a and 124b include: a first gas supply pipe (also denoted by 124a) disposed between the first heater 123a and the first silicon core rod 122a; and a second gas supply pipe (also denoted by 124b) disposed between the second heater 123b and the second silicon core rod 122b.

The gas injection nozzles 125 are disposed in surfaces of the gas supply pipes 124a and 124b such that the source gas introduced into the gas supply pipes 124a and 124b through the gas inlet 111 of the reactor 110 is directed to the first and second silicon core rods 122a and 122b. The source gas injected through the gas injection nozzles 125 is thermally decomposed, and the silicon gas formed by the decomposing is deposited on the first and second silicon core rods 122a and 122b. Since the source gas is introduced into the gas supply pipes 124a and 124b, is pre-heated by the first and second heaters 123a and 123b, and is injected to the first and second silicon core rods 122a and 122b, the source gas can be quickly decomposed.

Referring to FIGS. 1 and 2, the gas injection nozzles 125 include a plurality of nozzle groups 1251 each including at least two nozzles (also denoted by 125) that are spaced a predetermined distance from each other in the height direction of the surface of the first gas supply pipe 124a. The nozzle groups 1251 included in the gas injection nozzles 125 are spaced a predetermined distance from each other around the surface of the first gas supply pipe 124a. Accordingly, the gas injection nozzles 125 are uniformly arrayed near the first silicon core rod 122a, thereby improving silicon deposition efficiency. That is, the silicon gas formed by decomposing the source gas discharged from the gas injection nozzles 125 is deposited directly on the first silicon core rod 122a to form a silicon rod 210.

Referring to FIG. 1, the reactor 110 includes: a bottom cooling body 114 including a first cooling rod 114a at the inside thereof; a lower cooling body 115 disposed at an end of the bottom cooling body 114, and parallel to the first and second silicon core rods 122a and 122b, and including a second cooling rod 115a at the inside thereof; an upper cooling body 116 disposed on the top surface of the lower cooling body 115 and including a third cooling rod 116a at the inside thereof; and a dome cooling body 117 disposed on the upper cooling body 116 and including a fourth cooling rod 117a at the inside thereof.

The reactor 110 includes a coolant supplying device (not shown) to supply coolant to the first to fourth cooling rods 114a to 117a. When the source gas is supplied into the reactor 110, the coolant supplying device supplies coolest coolant to the second cooling rod 115a of the lower cooling body 115.

Most of the source gas is thermally decomposed, and is deposited on the first and second silicon core rod 122a and 122b, but a portion of silicon powder, which is not deposited on the first and second silicon core rods 122a and 122b, may be deposited on the reactor 110, for example, on the bottom cooling body 114, the lower cooling body 115, the upper cooling body 116, and the dome cooling body 117. Since the silicon powder is efficiently deposited at low temperature, the lower cooling body 115 is maintained at lowest temperature to induce the silicon powder to be deposited on the lower cooling body 115. This is because, if the amount of the silicon powder deposited on the dome cooling body 117 or the upper cooling body 116 is large, the quality of the silicon rod 210 may be degraded. In addition, if the amount of the silicon powder deposited on the bottom cooling body 114 is large, the gas outlet 112 may be clogged.

The poly silicon deposition device 100 includes a seeing through window 118 to see the inside of the reactor 110. The seeing through window 118 is used to measure the diameter of the silicon rod 210, and may be installed on the upper cooling body 116. A heating line may be attached to a glass part of the seeing through window 118 to prevent the silicon powder from being deposited thereon, so that the inside of the reactor 110 can be effectively seen.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A poly silicon deposition device disposed in an inner space of a reactor including a gas inlet for introducing source gas, a gas outlet for discharging gas, and a heating material inlet for introducing a heating material, the poly silicon deposition device thermally decomposing the source gas to deposit poly silicon, the poly silicon deposition device comprising:
an electrode part including a first electrode and a second electrode which are disposed in a bottom of the reactor and are spaced a predetermined distance from each other;
a silicon core rod part receiving electric current from the first electrode and transmitting the electric current to the second electrode to generate heat;
a silicon core rod heating part spaced a predetermined distance from the silicon core rod part and surrounding the silicon core rod part and including a heater receiving the heating material introduced through the heating material inlet of the reactor;
a gas supply pipe disposed between the heater and the silicon core rod part to supply the source gas introduced through the gas inlet of the reactor, to the silicon core rod part; and
a gas injection part including a plurality of nozzles disposed in a surface of the gas supply pipe to discharge the source gas to the silicon core rod part.

2. The poly silicon deposition device according to claim 1, wherein the heating material introduced through the heating material inlet of the reactor comprises oil heated to a predetermined temperature.

3. The poly silicon deposition device according to claim 1, wherein the silicon core rod part comprises:
a first silicon core rod connected to the first electrode and perpendicular to the bottom of the reactor;
a second silicon core rod connected to the second electrode and perpendicular to the bottom of the reactor; and
a third silicon core rod connecting the first and second silicon core rods to each other.

4. The poly silicon deposition device according to claim 3, wherein the silicon core rod heating part comprises:
a first heater spaced a predetermined distance from the first silicon core rod to surround the first silicon core rod, and receiving the heating material through the heating material inlet; and
a second heater spaced a predetermined distance from the second silicon core rod to surround the second silicon core rod, and receiving the heating material through the heating material inlet,
wherein the gas supply pipe comprises:
a first gas supply pipe disposed between the first heater and the first silicon core rod to supply the source gas introduced through the gas inlet, to the silicon core rod part; and
a second gas supply pipe disposed between the second heater and the second silicon core rod to supply the source gas introduced through the gas inlet, to the silicon core rod part.

5. The poly silicon deposition device according to claim 1, wherein the gas injection part comprises a plurality of nozzle groups each including at least two nozzles that are spaced a predetermined distance from each other in a height direction of the gas supply pipe, and
the nozzle groups are spaced a predetermined distance from each other around the surface of the gas supply pipe.

6. The poly silicon deposition device according to claim 1, wherein the reactor comprises:
a bottom cooling body including a first cooling rod at an inside thereof;
a lower cooling body vertically extending at an end of the bottom cooling body and including a second cooling rod at an inside thereof;
an upper cooling body disposed on a top surface of the lower cooling body and including a third cooling rod at an inside thereof;
a dome cooling body disposed on a top surface of the upper cooling body and including a fourth cooling rod at an inside thereof; and
a coolant supplying device for supplying coolant to the first to fourth cooing rods,
wherein, when the source gas is supplied into the reactor, the coolant supplying device supplies coolest coolant to the second cooling rod of the lower cooling body.

7. The poly silicon deposition device according to claim 6, wherein the reactor comprises:
a seeing through window for seeing an inside of the reactor; and
a heating line attached to the seeing through window.
